(19) United States
(12) Patent Application Publication
(10) Pub. No.: US 2006/0216942 A1
(43) Pub. Date: Sep. 28, 2006

(54) Wafer carrier for minimizing contacting area with wafers

(75) Inventors: Gi-Jung Kim, Yongin-si (KR); Sang-Mun Chon, Yongin-si (KR); Young-Nam Kim, Suwon-si (KR); Dae-Won Kang, Suwon-si (KR); Young-Sam Lim, Bucheon-si (KR)

Correspondence Address: F. CHAU & ASSOCIATES, LLC, 130 WOODBURY ROAD, WOODBURY, NY, 11797, US

(73) Assignee: Samsung Electronics Co., Ltd.

(21) Appl. No.: 11/373,425

(22) Filed: Mar. 10, 2006

(30) Foreign Application Priority Data
Mar. 23, 2005 (KR) 10-2005-24219

(51) Int. Cl. H01L 21/302; H01L 21/461

(52) U.S. Cl. 438/749

(57) ABSTRACT

A wafer carrier is provided. The wafer carrier includes a storage holding member for storing a plurality of wafers and includes a plurality of open portions. The wafer carrier further includes a front fixing plate and a rear fixing plate disposed at a front and a rear end of the storage holding member, respectively. The front and rear fixing plates each face a side of at least one of the plurality of wafers. Moreover, left and right edges of the plurality of wafers stored in the storage holding member are exposed by the plurality of open portions.

### PRIORITY STATEMENTS

This U.S. non-provisional application claims priority under 35 U.S.C. § 119 from Korean Patent Application No. 2005-24219, filed on Mar. 23, 2005 in the Korean Intellectual Property Office, the disclosure of which is incorporated by reference herein in its entirety.

### BACKGROUND OF THE INVENTION

1. Field of the Invention

The present invention relates to a wafer carrier, and more particularly, to a wafer carrier capable of minimizing the formation of foreign particles.

2. Description of the Related Art

A semiconductor wafer carrier is typically used as a protective device to transport semiconductor wafers stored therein during a manufacturing process. In particular, a conventional semiconductor wafer carrier usually has a plurality of slots in which multiple semiconductor wafers can be inserted.

However, as shown in FIG. 1, when a wafer W is stored in a conventional carrier 10, the contacting area therebetween is substantially large. That is, the contacting area between the wafer W and the carrier 10 covers an extensive area from an upper portion to a lower portion of the wafer. Accordingly, if foreign particles are present on the carrier 10, the foreign particles contaminate the wafer (W). Furthermore, when the contacting area between the carrier 10 and the wafer (W) is large, static electricity and friction-induced formation of foreign particles occur and the foreign particles adhere to the wafer W. Moreover, when foreign particles adhere to a wafer, the yield in semiconductor manufacturing is also reduced.

Accordingly, many attempts have been made to reduce the contacting area between a wafer carrier and a wafer to prevent the formation of foreign particles and reduction in yield. One such attempt is described in Korean Utility Model No. 20-2000-0002791. In the above-mentioned utility model, the carrier for a semiconductor wafer is a slot-type variation that contacts the wafer at its top and bottom portions only. Thus, the middle portion of the wafer does not contact the slot, thereby lessening the contacting area between the wafer and the carrier and also preventing the creation of static electricity and friction-induced foreign particles that may cause a reduction in yield.

However, the above-described conventional semiconductor wafer carrier has certain difficulties associated therewith. For example, this conventional semiconductor wafer carrier has a structure that covers the sides of the slot. When a wafer stored in a carrier having a structure with covered sides, is washed, not only is the washing effectiveness for the wafer reduced, but there is also the possibility that foreign particles will remain on the wafer or the inner surface of the carrier. Therefore, when a wafer is washed in this conventional carrier, complete removal of foreign particles is difficult to achieve, and residual foreign particles may adhere to the wafer, contaminating it and thus also causing a loss in yield.

Thus, there is a need for a wafer carrier which is more effective than conventional wafer carriers at reducing the formation of foreign particles and the adherence of foreign particles to the wafers stored within the carrier.

### SUMMARY OF THE INVENTION

In an exemplary embodiment of the present invention, a wafer carrier is provided. The wafer carrier includes a storage holding member for storing a plurality of wafers and includes a plurality of open portions. The wafer carrier further includes a front fixing plate and a rear fixing plate disposed at a front and a rear end of the storage holding member, respectively. The front and rear fixing plates each face a side of at least one of the plurality of wafers. Moreover, left and right edges of the plurality of wafers stored in the storage holding member are exposed by the plurality of open portions.

In further exemplary embodiments, the storage holding member further includes: a side support disposed in opposition for supporting the wafers at left and right mid portion edges of the wafers; a lower support disposed in opposition for supporting the wafers at left and right lower portion edges of the wafers; and a connecting portion for structurally connecting the side support and the lower support. Accordingly, the plurality of open portions can be arranged by the empty spaces between the side and lower supports and the connecting portion.

In another exemplary embodiment, the front fixing plate and the rear fixing plate respectively expose a partial surface of wafers in a foremost and a rearmost row of the storage holding member. Here, the front fixing plate and the rear fixing plate have at least one of an opening and a cut-out portion.

In yet another exemplary embodiment of the present invention, the storage holding portion has a height equal to or greater than a height at a middle of the wafers stored therein.

In a further exemplary embodiment of the present invention, a wafer carrier includes: a storage holding member for storing a plurality of wafers upright and in a column; a front fixing plate provided at a front end of the storage holding member and opposite to a surface of a wafer stored in a foremost row of the storage holding member; and a rear fixing plate provided at a rear end of the storage holding member and opposite to a surface of a wafer stored in a rearmost row of the storage holding member.

In another exemplary embodiment of the present invention, the storage holding member includes a side support disposed in opposition for supporting the wafers at left and right mid portion edges of the plurality of wafers and a lower support disposed in opposition for supporting the wafers at left and right lower portion edges of the plurality of wafers. Here, the side support and the lower support are structurally connected by a vertically extending connecting portion and a plurality of open portions are formed between the side and lower supports and the connecting portion for exposing left and right edge portions of the wafers.

In still another exemplary embodiment of the present invention, the storage holding member has a height equal to a height at a top of the wafers. Also, the front fixing plate and the rear fixing plate have a height equal to the height at the top of the wafers.

In a further exemplary embodiment of the present invention, the front fixing plate and the rear fixing plate include an opening formed for exposing a partial surface of the wafers. Moreover, the front fixing plate and the rear fixing plate further include respective cut-out portions removed from a top thereof for exposing a partial surface of the wafers.

In a still further exemplary embodiment of the present invention, the open portion exposes left and right edges of the wafers. Also, the storage holding member has a height equal to a height at a middle of the wafers.

In another exemplary embodiment of the present invention, the front fixing plate and the rear fixing plate have a height equal to a height at a middle of the wafers. Here, the front fixing plate and the rear fixing plate further include an opening for exposing a partial surface of the wafers. Also, the front fixing plate and the rear fixing plate further include respective cut-out portions removed from a top thereof for exposing a partial surface of the wafers.

In another exemplary embodiment of the present invention, the wafer is supported in an upright position by contacting the wafer carrier only at the left and right and lower edges of the wafer, thereby reducing its direct contacting area with the wafer carrier. By reducing the contacting area, the occurrence of contact-induced foreign particles is reduced. In case the wafer carrier of the present invention is employed, during washing of the wafer, washing effectiveness of the wafer's edges and overall surface increases.

In another exemplary embodiment of the present invention, a method for using a wafer carrier is provided. The method includes providing a wafer carrier which includes a storage holding member for storing a plurality of wafers and including a plurality of open portions, and a front fixing plate and a rear fixing plate disposed at a front and a rear end of the storage holding member, respectively. The front and rear fixing plates each face a side of at least one of the plurality of wafers. Also, the left and right edges of the plurality of wafers stored in the storage holding member are exposed by the plurality of open portions. In addition, the method further includes placing at least one of the plurality of wafers into the storage holding member of the wafer carrier.

### BRIEF DESCRIPTION OF THE DRAWINGS

The accompanying drawings, which are included to provide a further understanding of the invention and are incorporated in and constitute a part of this application, illustrate exemplary embodiment(s) of the invention and together with the description serve to explain the principle of the invention. In the drawings:

FIG. 1 is a front sectional view of a conventional wafer carrier;

FIG. 2 is a side view of a wafer carrier according to an exemplary embodiment of the present invention;

FIG. 3 is a plan view of a wafer carrier in FIG. 2;

FIG. 4 is a front view of the wafer carrier in FIG.2;

FIGS. 5 and 6 are front views of the wafer carrier in FIG. 2 showing different examples of a fixing plate;

FIG. 7 is a side view of a wafer carrier according to an exemplary embodiment of the present invention; and

FIG. 8 is a front view of the wafer carrier in FIG. 7.

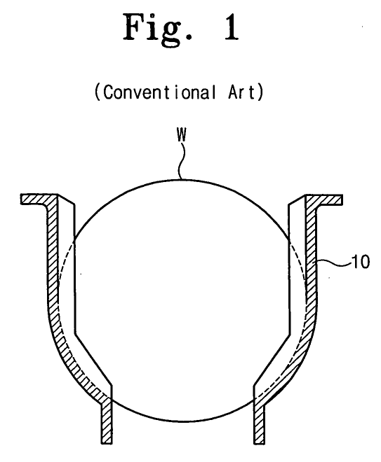

### DETAILED DESCRIPTION OF THE EXEMPLARY EMBODIMENTS OF THE INVENTION

Reference will now be made in detail to the exemplary embodiments of the present invention, examples of which are illustrated in the accompanying drawings.

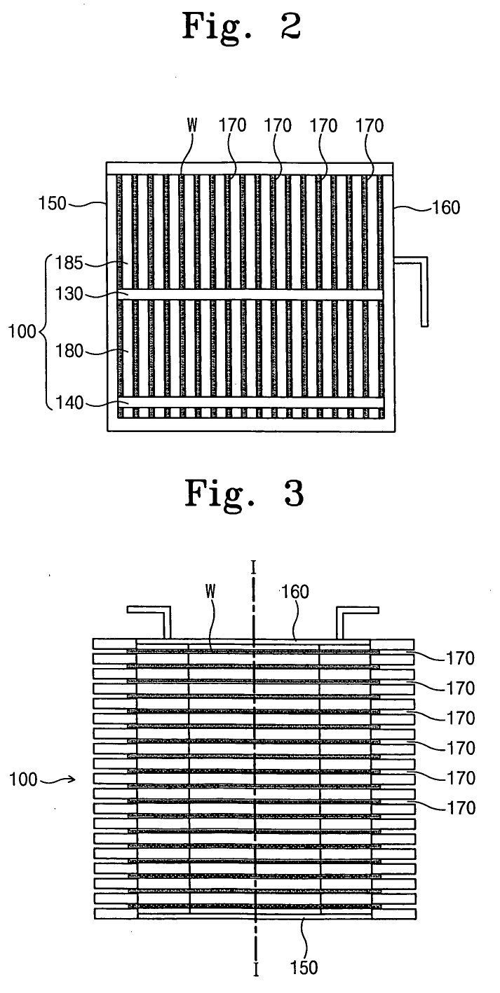

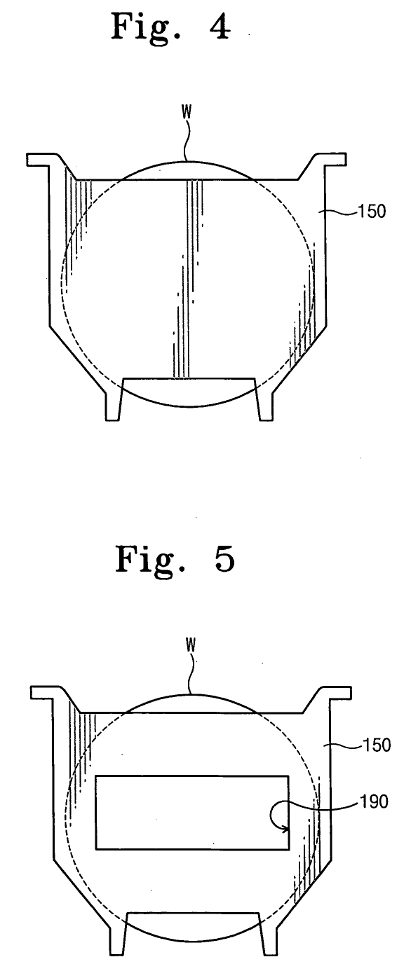

FIG. 2 is a side view of a wafer carrier according to an exemplary embodiment of the present invention, FIG. 3 is a plan view of the wafer carrier in FIG. 2, and FIG. 4 is a front view of the wafer carrier in FIG. 2.

Referring to FIGS. 2 through 4, a wafer carrier according to an exemplary embodiment of the present invention includes a storage holding member 100 capable of storing a plurality of semiconductor wafers W upright and in a row with an adequate gap between the wafers. The wafer carrier also has a front fixing plate 150 and a rear fixing plate 160 disposed respectively at the front and rear of the wafer carrier along the axial line I of the storage holding member 100. The top and bottom of the wafer carrier are open.

The storage holding member 100 further includes a side support 130 disposed on either side thereof for receiving the middle portions of the left and right edges of the wafer W. In addition, the storage holding member 100 includes a lower support 140 disposed opposite to the side support 130 on either side of the storage holding member 100 for receiving the lower portions of the left and right edges of the wafer W. The lower support 140 is located within the parameter formed by the side support 130 and below the side support 130. The side support 130 is disposed at a height that is roughly equal to the height of the middle portion of the wafer W.

The side support 130 and the lower support 140 extend along the axial line (I) direction of the storage holding member 100. In addition, between the side support 130 and the lower support 140 are a plurality of lower connecting portions 180 elongated perpendicularly to and arranged along the axial line I. Moreover, a plurality of upper connecting portions 185, extend from the lower connecting portions 180 past the side support 130 to the top of the wafer W. This plurality of upper connecting portions 185 is elongated perpendicularly to and are arranged along the axial line I. The empty spaces between the side supports 130 and the lower supports 140 and the upper and lower connecting portions 180 and 185 in this structure will hereinafter be referred to as open portions 170. Thus, the storage holding member 100 has a plurality of open portions 170 extending in a diametric direction of the wafer W on either side thereof, and the left and right edges of the stored and held wafers W in the open portions 170 are exposed to the outside.

The open portion 170 allows the left and right edges of the wafer W to be exposed to the outside and has a width slightly larger than the thickness of the wafer W to avoid contacting the edges of the wafer W. Moreover, a plurality of open portions 170 are arranged along the axial line I. The number of the plurality of open portions 170 used with the wafer carrier are determined by the maximum number of wafers W that the wafer carrier can accommodate inside. Also, when the storage holding member 100 is viewed from the side, most of the edge portions of the wafer W, with the exception of the central and lower left and right edge portions, are visible from the outside.

It is further noted that even in situations when the wafer carrier of this exemplary embodiment, having the storage holding portion 100 with a plurality of open portions 170, shares the same structural properties ( e.g., size, material, etc.) with conventional wafer carriers, the wafer carrier of this exemplary embodiment will still be lighter than these conventional wafer carriers, thereby also making it more manageable to handle.

The front fixing plate 150 opposite the foremost wafer W stored in the wafer carrier may be designed to have a height almost equal to that of the wafer W. Similarly, the rear fixing plate 160 opposite the rearmost wafer W stored in the wafer carrier may be designed to have a height almost equal to that of the wafer W. When the front fixing plate 150 and the rear fixing plate 160 have a height almost equal to the height of the wafer W, the wafers can be protected from damage, especially the foremost and rearmost wafers W. For example, when wafers W are placed in the wafer carrier, the wafers can be protected from chemicals or solid particles flying toward the wafer carrier.

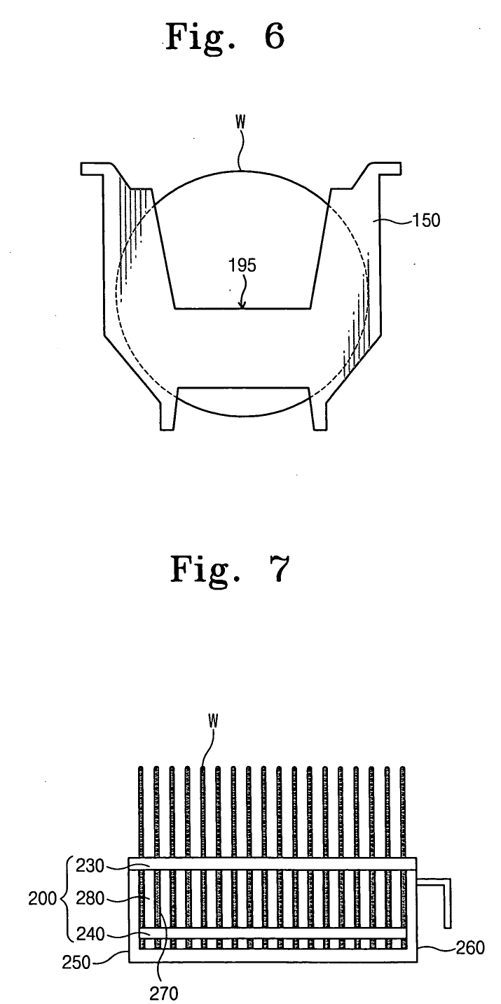

FIGS. 5 and 6 are front views of the wafer carrier in FIG. 2 showing different examples of a fixing plate. Referring to FIG. 5, an opening 190 may be further formed so that the front of the wafer W, opposite the front fixing plate 150 at the front end of the wafer carrier, is visible. As described below, when the opening 190 is formed in the front fixing plate 150 and the wafer carrier is used for washing the wafers, both the amount of residual washing liquid between the foremost wafer W and the inside of the opposing front fixing plate 150 as well as the formation of foreign particles can be reduced. For example, foreign particles formed can mix with running wash liquid and be washed away from the wafer carrier through the opening 190, reducing the chances of the foreign particles reattaching to the wafer W. In this exemplary embodiment, the rear fixing plate 160 opposite the rearmost wafer W is the same in the above aspects as the front fixing plate 150.

Referring to FIG. 6, the top of the front fixing plate 150 opposite the foremost wafer W has a predetermined shape, for example, a ladder-shaped recess formed by a cut-out portion 195. By forming the cut-out portion 195 at the top of the front fixing plate 150, the formation of foreign particles or the reattaching of foreign particles on the wafer W can be reduced, as described in the preceding paragraph. The rear fixing plate 160 is treated the same.

Referring again to FIGS. 2 through 4, the wafer W stored inside the wafer carrier contacts the storage holding member 100 at only the central and lower left and right edges of the wafer W. The remaining edge portions of the wafer W do not contact the storage holding member 100, and accordingly, the contacting area between the wafer carrier and the wafer W is minimized. Thus, the chances of impurity formation caused by friction or static electricity from direct contact between the wafer carrier and the wafer W are minimized. Even if foreign particles should adhere to a wafer W, the chances of the foreign particles transferring from the wafer W to the wafer carrier through direct contact, and then from the wafer carrier to another wafer W to contaminate it, are minimized.

The wafer carrier of this exemplary embodiment may be employed as a wafer washing carrier. During washing of the wafer, when the wafer carrier holding the wafer W is immersed in a washing tub, the washing liquid can, for example, circulate through the wafer carrier by entering through the left of and exiting through the right of the open portion 170. Here, by entering and exiting through the open portion 170, the washing liquid is made to flow between the wafers W, and is thus more effective at removing foreign particles than in a conventional carrier with closed sides. Even with its open sides, the wafer carrier of this exemplary embodiment allows washing liquid to flow through the narrow open portions 170. Accordingly, the flowing speed of washing liquid between the wafers W increases so that foreign particles on the front and back of the wafer are easily removed, and the removed foreign particles are not retained near the wafer to prevent the possibility of the foreign particles from re-adhering to the wafer W. Conversely, when washing liquid flows from the lower to the upper portion of the wafer, the washing liquid can enter from the bottom and flow out from the left and right sides of the open portion 170. With the wafer carrier of the present exemplary embodiment, washing liquid can flow from the bottom to the top or from the left to the right sides of the wafer W, thereby increasing washing effectiveness. Additionally, because the edge portion of the wafer W is exposed almost entirely by means of the open portion 170, during heat treating, foreign particles accumulated on the edge of the wafer W can be effectively removed.

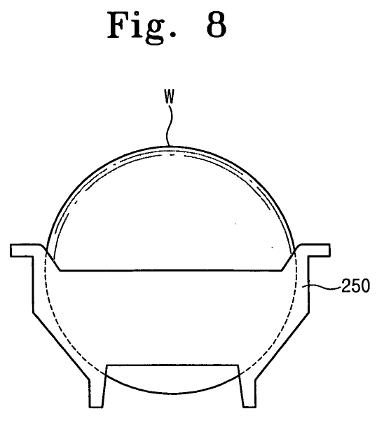

FIGS. 7 and 8 illustrate an exemplary embodiment of the wafer carrier according to the present invention. The wafer carrier of this exemplary embodiment is slightly different from the previous exemplary embodiment shown in FIG. 2, as will be apparent from the description below.

Referring to FIGS. 7 and 8, the wafer carrier of this exemplary embodiment includes a storage holding member 200 that has a plurality of open portions 270 formed therein for exposing the lower left and right edges of the wafer W stored in the storage holding member 200. The height of the upper portion of the storage holding member 200 is approximately equal to the height at the middle of the wafer W. Also, the heights of the fixing plates 250 and 260 disposed at the front and rear end of the wafer carrier are approximately equal to the height at the middle of the wafer W held in the wafer carrier. The empty spaces between the side supports 230 and the lower supports 240 and the upper and lower connecting portions 280 in this structure will hereinafter be referred to as open portions 270.

Due to the open portion 270 that exposes the lower left and right edges of the wafer W in the storage holding member 200, direct contact with the wafer W can be minimized and the possibility of impurity formation can be reduced. Also, because the height of the storage holding member 200 is reduced, clashing of the wafer W against the wafer carrier during loading and unloading of the wafer W can be minimized. In addition to above-described facilitated impurity removal from the wafer W by the washing liquid and reduced impurity formation, the wafer carrier of the present exemplary embodiment also minimizes the colliding between the front and rear fixing plates 250 and 260 with the wafer W during its loading and unloading because the height of the front and rear fixing plates 250 and 260 is reduced.

As in the exemplary embodiment of the wafer carrier shown in FIGS. 5 and 6, a further opening or cut-out portion may be formed on each of the fixing plates 250 and 260. The characteristics of such formations on the respective fixing plates 250 and 260 have already been described.

As described above, the wafer carrier of the exemplary embodiments of the present invention minimizes the contacting area with a wafer stored inside, thereby reducing the contact-induced formation of foreign particles or adherence of foreign particles to the wafer. Thus, when the wafer carrier of the exemplary embodiments of the invention are used, the productivity or yield of semiconductor devices increases. Also, the weight of the wafer carrier of the exemplary embodiments is lighter than conventional wafer carriers, thereby making handling thereof simple and easy.

Having described the exemplary embodiments of the present invention, it is further noted that it is readily apparent to those of reasonable skill in the art that various modifications may be made without departing from the spirit and scope of the invention which is defined by the metes and bounds of the appended claims.

What is claimed is:

1. A wafer carrier comprising:
a storage holding member for storing a plurality of wafers and comprising a plurality of open portions; and
a front fixing plate and a rear fixing plate disposed at a front and a rear end of the storage holding member, respectively, the front and rear fixing plates each facing a side of at least one of the plurality of wafers,
wherein left and right edges of the plurality of wafers stored in the storage holding member are exposed by the plurality of open portions.

2. The wafer carrier of claim 1, wherein the storage holding member further comprises:
a side support for supporting the wafers at left and right mid portion edges of the wafers;
a lower support disposed for supporting the wafers at left and right lower portion edges of the wafers; and
a connecting portion for structurally connecting the side support and the lower support.

3. The wafer carrier of claim 1, wherein the front fixing plate and the rear fixing plate respectively expose a partial surface of wafers in a foremost and a rearmost row of the storage holding member.

4. The wafer carrier of claim 3, wherein the front fixing plate and the rear fixing plate respectively have at least one of an opening and a cut-out portion.

5. The wafer carrier of claim 1, wherein the storage holding portion has a height equal to or greater than a height at a middle of the wafers stored therein.

6. A wafer carrier comprising:
a storage holding member for storing a plurality of wafers substantially upright;
a front fixing plate provided at a front end of the storage holding member and opposite to a surface of a wafer stored in a foremost row of the storage holding member; and
a rear fixing plate provided at a rear end of the storage holding member and opposite to a surface of a wafer stored in a rearmost row of the storage holding member;
wherein the storage holding member includes a side support for supporting the plurality of wafers at left and right mid portion edges of the wafers and a lower support for supporting the plurality of wafers at left and right lower portion edges of the wafers, and the side support and the lower support are structurally connected by a vertically extending connecting portion, and a plurality of open portions are formed between the respective side and lower supports and the connecting portion for exposing left and right edge portions of the wafers.

7. The wafer carrier of claim 6, wherein the storage holding member has a height equal to a height at a top of the wafers.

8. The wafer carrier of claim 7, wherein the front fixing plate and the rear fixing plate have a height equal to the height at the top of the wafers, respectively.

9. The wafer carrier of claim 8, wherein the front fixing plate and the rear fixing plate further comprise an opening formed for exposing a partial surface of the wafers, respectively.

10. The wafer carrier of claim 8, wherein the front fixing plate and the rear fixing plate further comprise cut-out portions removed from tops thereof for exposing a partial surface of the wafers, respectively.

11. The wafer carrier of claim 6, wherein the open portion has a width appropriate for exposing left and right edges of the wafers.

12. The wafer carrier of claim 6, wherein the storage holding member has a height equal to a height at a middle of the wafers.

13. The wafer carrier of claim 12, wherein the front fixing plate and the rear fixing plate have a height equal to the height at the middle of the wafers, respectively.

14. The wafer carrier of claim 13, wherein the front fixing plate and the rear fixing plate further comprise an opening for exposing a partial surface of the wafers, respectively.

15. The wafer carrier of claim 13, wherein the front fixing plate and the rear fixing plate further comprise cut-out portions removed from tops thereof for exposing a partial surface of the wafers, respectively.

16. A method for using a wafer carrier comprising:
providing a wafer carrier comprising a storage holding member for storing a plurality of wafers and comprising a plurality of open portions; and a front fixing plate and a rear fixing plate disposed at a front and a rear end of the storage holding member, respectively, the front and rear fixing plates each facing a side of at least one of the plurality of wafers, and
wherein left and right edges of the plurality of wafers stored in the storage holding member are exposed by the plurality of open portions;
placing at least one of the plurality of wafers into the storage holding member of the wafer carrier; and
immersing the wafer carrier holding at least one of said plurality of wafers therein into a washing apparatus.

17. The method of claim 16, wherein the washing apparatus is a washing tub.

18. The method of claim 16, wherein the storage holding member further comprises:
a side support for supporting the wafers at left and right mid portion edges of the wafers;
a lower support disposed for supporting the wafers at left and right lower portion edges of the wafers; and
a connecting portion for structurally connecting the side support and the lower support.

19. The method of claim 16, wherein the front fixing plate and the rear fixing plate respectively have at least one of an opening and a cut-out portion.

20. The method of claim 16, wherein the storage holding portion has a height equal to or greater than a height at a middle of the wafers stored therein.
